(19) United States
(12) Patent Application Publication
(10) Pub. No.: US 2026/0088071 A1
(43) Pub. Date: Mar. 26, 2026

(54) SEMICONDUCTOR DEVICE

(71) Applicant: Samsung Electronics Co., Ltd., Suwon-si (KR)

(72) Inventors: Sunggyeong Lee, Suwon-si (KR); Hyunchul Yoon, Suwon-si (KR)

(21) Appl. No.: 19/268,882

(22) Filed: Jul. 14, 2025

(30) Foreign Application Priority Data
Sep. 23, 2024 (KR) 10-2024-0128238

(51) Int. Cl. G11C 11/22; G11C 5/06; H10B 53/10; H10B 53/20; H10B 53/40

(52) U.S. Cl. CPC G11C 11/221; G11C 5/063; G11C 11/2255; G11C 11/2257; G11C 11/2259; G11C 11/2297; H10B 53/10; H10B 53/20; H10B 53/40

(57) ABSTRACT

A semiconductor device includes memory cell groups connected to word lines, bit lines, and plate lines, each memory cell group including first and second switching elements and capacitors connected to the first switching element and including a ferroelectric layer, the second switching element connected between a first node between the first switching element and the capacitors and a second node supplying a predetermined voltage. In each of the memory cell groups, the capacitors are connected to different plate lines. A turn-on voltage is applied to a selected word line connected to a selected memory cell group, and turns on the first switching element included in the selected memory cell group. While the selected memory cell group is activated, the predetermined voltage is applied to unselected plate lines connected to unselected memory cell groups, and turns on the second switching element included in each of the unselected memory cell groups.

### CROSS-REFERENCE TO RELATED APPLICATION(S)

This application claims the benefit of priority under 35 U.S.C. § 119 of Korean Patent Application No. 10-2024-0128238, filed on Sep. 23, 2024, in the Korean Intellectual Property Office, the entire disclosure of which is incorporated herein by reference for all purposes.

### BACKGROUND

The present inventive concept relates to a semiconductor device.

Semiconductor devices provide functions to write data to and erase data from memory cells, or to read written data from memory cells, and memory cells may write data in various manners. Recently a Ferroelectric Random Access Memory (FeRAM) has been proposed as a semiconductor device capable of writing data, including a ferroelectric layer, and such a FeRAM has the advantage of having non-volatile characteristics that maintain data even when power is cut off, while also operating at high speed. A FeRAM writes data by changing the polarization state of the ferroelectric layer, and therefore, controlling the polarization state of the ferroelectric layer may have a significant impact on the performance of FeRAM.

### SUMMARY

Example embodiments provide a semiconductor device having improved reliability and performance by blocking a coupling effect between a selected plate line and an unselected plate line by applying the same voltage to respective electrodes of capacitors connected to an unselected word line.

According to example embodiments, a semiconductor device includes a cell region provided with memory cell groups connected to word lines, bit lines, and plate lines, each of the memory cell groups including a first switching element, a second switching element, and capacitors connected to the first switching element and including a ferroelectric layer, the second switching element being connected between a first node between the first switching element and the capacitors and a second node supplying a predetermined voltage; and a peripheral circuit region controlling the cell region through the word lines, the bit lines, and the plate lines. In each of the memory cell groups, the capacitors are connected to the plate lines different from each other. The peripheral circuit region applies a turn-on voltage to a selected word line connected to a selected memory cell group among the memory cell groups, from among the word lines, and turns on the first switching element included in the selected memory cell group. While the selected memory cell group is activated, the peripheral circuit region applies the predetermined voltage to unselected plate lines connected to unselected memory cell groups excluding the selected memory cell group among the memory cell groups, and turns on the second switching element included in each of the unselected memory cell groups.

According to example embodiments, a semiconductor device includes a first region including a plurality of memory cell groups, each of the plurality of memory cell groups including a first switching element, a second switching element, and a plurality of capacitors including a ferroelectric layer; and a second region including a plurality of word line driving circuits, a plurality of sense amplifier circuits, and a plurality of plate line drivers. The first region includes a plurality of word lines extending in a first direction, a plurality of bit lines extending in a second direction perpendicular to the first direction, and a plurality of plate lines. The first switching element is connected to one of the plurality of word lines and one of the plurality of bit lines. The plurality of plate lines are disposed on the plurality of word lines, the plurality of bit lines, and the second switching element in a third direction, perpendicular to the first direction and the second direction, and are stacked in the third direction. In each of the memory cell groups, the plurality of capacitors penetrate the plurality of plate lines in the third direction, and the capacitors are connected to the plurality of plate lines different from each other. The second switching element is connected to a voltage source located between the first switching element and the plurality of capacitors and set to a predetermined voltage.

According to example embodiments, a semiconductor device includes a plurality of word lines; a plurality of bit lines; a plurality of plate lines; and a plurality of memory cell groups connected to the plurality of word lines, the plurality of plate lines, and the plurality of bit lines. Each of the plurality of memory cell groups includes a first switching element, a second switching element, and a plurality of capacitors connected to the first switching element and including a ferroelectric layer. In each of the plurality of memory cell groups, the first switching element is connected to one of the word lines and one of the bit lines, the plurality of capacitors are connected to the plurality of plate lines different from each other, and the second switching element is connected between the first switching element and the plurality of capacitors.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a block diagram simply illustrating a semiconductor device according to an example embodiment;

FIG. 2 is a diagram simply illustrating a memory cell array included in a semiconductor device according to an example embodiment;

FIG. 3 is a circuit diagram simply illustrating a memory cell included in a memory cell array according to an example embodiment;

FIG. 4 is a diagram simply illustrating a memory cell array included in a semiconductor device according to an example embodiment;

FIG. 5 is a diagram illustrating an operation of the memory cell array of an example embodiment illustrated in FIG. 4;

FIG. 6 is a diagram illustrating characteristics of a memory cell included in a semiconductor device according to an example embodiment;

FIG. 7 and FIG. 8 are diagrams illustrating program operations of a semiconductor device according to an example embodiment;

FIG. 9 is a diagram illustrating a read operation of a semiconductor device according to an example embodiment;

FIG. 10 is a diagram simply illustrating a memory cell array included in a semiconductor device according to an example embodiment;

FIG. 11 is a diagram illustrating an operation of the memory cell array of an example embodiment illustrated in FIG. 10;

FIG. 12 is a diagram illustrating a memory cell array included in a semiconductor device according to an example embodiment;

FIG. 13 is a plan view illustrating a semiconductor device according to an example embodiment;

FIG. 14 is a cross-sectional view illustrating a cross-section in direction I-I′ of the semiconductor device illustrated in FIG. 13; and

FIG. 15 is a cross-sectional view illustrating a cross-section in direction II-II′ of the semiconductor device illustrated in FIG. 13.

### DETAILED DESCRIPTION

Hereinafter, example embodiments will be described with reference to the accompanying drawings. Like reference characters refer to like elements throughout.

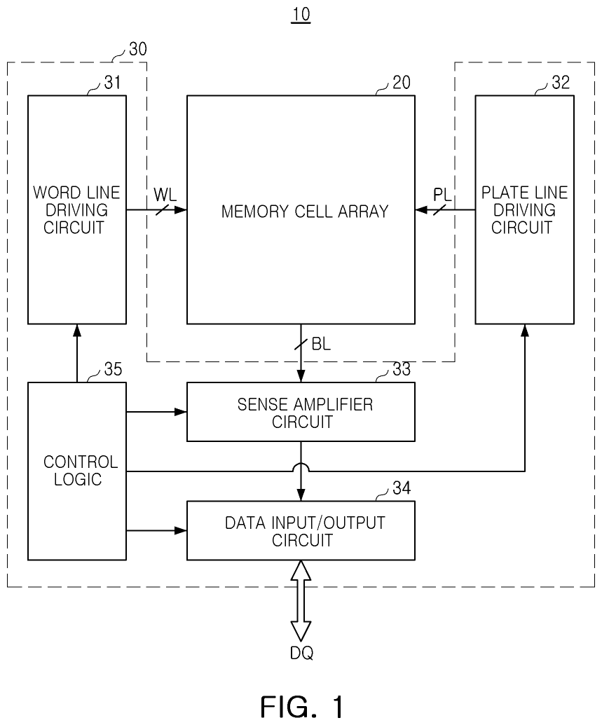

FIG. 1 is a block diagram simply illustrating a semiconductor device according to an example embodiment.

Referring to FIG. 1, a semiconductor device 10 according to an example embodiment may be a storage device based on a semiconductor element. The semiconductor device 10 may be a random access memory (RAM) device and may be applied as a main memory to electronic devices such as desktop computers, laptop computers, tablet PCs, and smartphones. The semiconductor device 10 may store data received as a data signal (DQ) in response to an address signal and a control command signal received from an external host (for example, a central processing unit (CPU), an application processor (AP), a system on a chip (SoC), or the like), or may read the stored data and output the read data as a data signal (DQ).

The semiconductor device 10 may include a cell region 20, a peripheral circuit region 30, and the like. The cell region 20 includes a plurality of memory cells, and the plurality of memory cells may form a memory cell array. The peripheral circuit region 30 may include a word line driving circuit 31, a plate line driving circuit 32, a sense amplifier circuit 33, a data input/output circuit 34, a control logic 35, and the like, and may control the cell region 20.

The plurality of memory cells included in the cell region 20 may be connected to word lines WL, bit lines BL, and plate lines PL to form a memory cell array. The plurality of memory cells may be connected to the word line driving circuit 31 through the word lines WL and to the plate line driving circuit 32 through the plate lines PL. Meanwhile, the plurality of memory cells are connected to the sense amplifier circuit 33 through the bit lines BL, and the sense amplifier circuit 33 may perform a program operation, a read operation, and the like through the bit lines BL. The plurality of memory cells may respectively be positioned at points where word lines WL and bit lines BL intersect.

Each of the plurality of memory cells may include a first switching element and a capacitor connected to the first switching element, and the capacitor may include electrodes and a ferroelectric layer. In an example embodiment, the plurality of memory cells may respectively form a plurality of memory cell groups. Each of the plurality of memory cell groups may include a first switching element, capacitors, and a second switching element connected between the first switching element and the capacitors. The capacitors may share the first switching element. Among the electrodes included in the capacitor, a first electrode may be connected to the first switching element and the second switching element, and a second electrode may be connected to a plate line (PL).

Meanwhile, each of the first switching element and the second switching element may be implemented as a transistor. A gate of a first switching element may be connected to a word line WL, one of the source/drain regions of the first switching element may be connected to a first electrode of a capacitor, and another of the source/drain regions of the first switching element may be connected to a bit line BL. A gate of a second switching element may be connected to a second switch control line, one of the source/drain regions of the second switching element may be connected to a voltage source set to a predetermined voltage, and another of the source/drains of the second switching element may be connected to the first electrode of the capacitor. The peripheral circuit region 30 may record data by changing a polarization state and a polarization degree of a ferroelectric layer included in a capacitor included in a memory cell group.

The control logic 35 may receive an address signal and a control command signal from an external host. The address signal may include a row address indicating a row in the memory cell array of the cell region 20 and a column address indicating a column in the memory cell array. For example, the word line driving circuit 31 may determine a selected word line among a plurality of word lines WL by referring to the row address, and the plate line driving circuit 32 and the sense amplifier circuit 33 may determine a selected plate line and a selected bit line by referring to the column address.

The sense amplifier circuit 33 may include a plurality of sense amplifiers connected to the cell region 20 through a plurality of bit lines BL. For example, when a read operation is executed, a sense amplifier connected to a selected bit line may read data from a selected capacitor connected to the selected bit line. The data input/output circuit 34 may output the data read by the sense amplifier, as a data signal (DQ).

Meanwhile, when the program operation is executed, a predetermined program voltage may be applied to the selected bit line and the selected plate line connected to the selected memory cell while the first switching element included in the selected memory cell group is turned on and the second switching element is turned off. In detail, a predetermined program voltage may be applied to the selected bit line and the selected plate line connected to the selected capacitor. In an example embodiment, the program voltage is determined by the difference between the voltage applied to the selected plate line and the voltage applied to the selected bit line, and the polarization degree of the ferroelectric layer included in the selected capacitor may be changed by the program voltage. The polarization degree may be a concept including the polarization direction and the polarization degree of the ferroelectric layer.

In this manner, the polarization degree of the ferroelectric layer included in the capacitor may be changed by the voltage applied to the capacitor. The polarization degree of the ferroelectric layer and the voltage applied to the capacitor may have a relationship defined by a hysteresis curve. When a specific voltage is continuously applied to the capacitor, the relationship between the voltage and the polarization expressed by the hysteresis curve may change, which may lead to a decrease in the characteristics of the memory cell and the performance of the semiconductor device 10.

A general semiconductor device may not include a second switching element. In a general semiconductor device, when the first switching element included in the selected memory cell group is turned on, a predetermined program voltage may be applied to the selected bit line and the selected plate line connected to the selected memory cell connected to the selected capacitor. At this time, when the first switching element included in the unselected memory cell group is turned off, the unselected bit line and/or the unselected plate line may be floated.

In a general semiconductor device, electrical interference may occur due to a coupling effect between the selected plate line and the unselected plate line adjacent to the selected plate line. In detail, the coupling effect may cause an unintended voltage difference between the electrodes of the unselected capacitor connected to the unselected plate line. Accordingly, data stored in the unselected capacitor may be damaged or changed, and leakage current may occur in the unselected capacitor, which may lead to a deterioration in the performance and reliability of the semiconductor device.

The semiconductor device 10 of an example embodiment may reduce the coupling effect between the selected plate line and the adjacent unselected plate line by including the second switching element. In detail, the first switching element may be turned off and the second switching element may be turned on to apply a predetermined voltage of the voltage source to the first electrode of the unselected capacitor. By applying the predetermined voltage equally to the unselected plate line, the predetermined voltage may also be applied to the second electrode of the unselected capacitor, thereby enabling to control to prevent a voltage difference between the electrodes of the unselected capacitor from occurring.

The semiconductor device 10 of an example embodiment may prevent data stored in the unselected capacitor from being damaged or changed. In addition, by preventing the occurrence of leakage current in the unselected capacitor, the performance deterioration of the semiconductor device 10 may be minimized, thereby improving reliability.

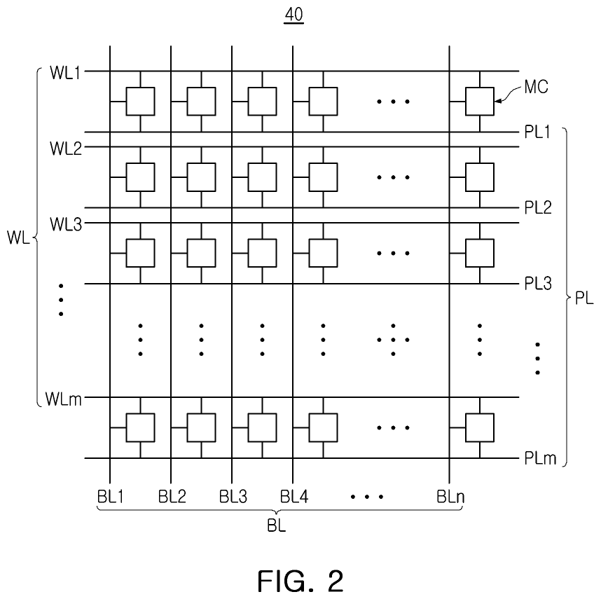

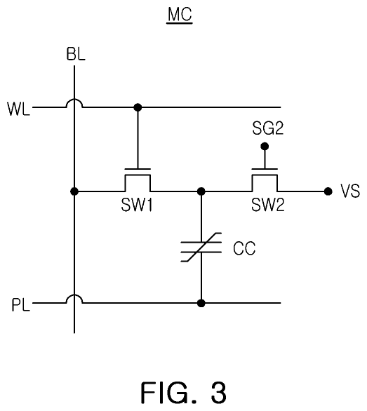

FIG. 2 is a diagram simply illustrating a memory cell array included in a semiconductor device according to an example embodiment. FIG. 3 is a circuit diagram simply illustrating a memory cell included in a memory cell array according to an example embodiment.

First, referring to FIG. 2, a memory cell array 40 according to an example embodiment may include a plurality of memory cells MC connected to a plurality of word lines (WL1-WLm: WL), a plurality of plate lines (PL1-PLm: PL), and a plurality of bit lines (BL1-BLn: BL). The number of the plurality of word lines WL, the plurality of plate lines PL, the plurality of bit lines BL, and the plurality of memory cells MC may vary depending on example embodiments. The plurality of memory cells MC may be disposed at points where the plurality of word lines WL, the plurality of plate lines PL, and the plurality of bit lines BL intersect.

As described above with reference to FIG. 1, a plurality of word lines WL may be connected to a word line driving circuit (e.g., word line driving circuit 31), a plurality of plate lines PL may be connected to a plate line driving circuit (e.g., plate line driving circuit 32), and a plurality of bit lines BL may be connected to a sense amplifier circuit (e.g., sense amplifier circuit 33). When a selected word line selected by the word line driving circuit and a selected plate line selected by the plate line driving circuit are determined, a program operation, a read operation, a recovery operation, and the like may be executed for selected memory cells connected to the selected word line and the selected plate line. The plurality of bit lines BL are respectively connected to different sense amplifiers included in the sense amplifier circuit, and thus, the selected memory cells may be respectively, individually controlled.

Referring to FIG. 3, a memory cell MC included in a semiconductor device according to an example embodiment may include a first switching element SW1, a second switching element SW2, and a capacitor CC.

The first switching element SW1 may be implemented as a transistor, and the gate may be connected to a word line WL. Meanwhile, one of the source/drain regions of the first switching element SW1 may be connected to a bit line BL, and the other may be connected to a capacitor CC. The capacitor CC may include a ferroelectric layer and may be connected to a plate line PL.

The second switching element SW2 may be implemented as a transistor. The gate of the second switching element may be connected to a second switch control line SG2, one of the source/drain regions of the second switching element may be connected to a voltage source set to a predetermined voltage VS, and the other of the source/drains of the second switching element may be connected to a capacitor CC.

When a memory cell MC of a semiconductor device is selected by an address signal received from an external host or the like, a first switching element SW1 may be turned on by a voltage applied to a word line WL, and a second switching element SW2 may be turned off by a voltage applied to a second switch control line SG2. For example, the voltage applied to the second switch control line SG2 may have a phase opposite to a phase of the voltage applied to the word line WL. In detail, while the first switching element SW1 is turned on/off, the second switching element SW2 may be turned off or on. However, the phases of the voltages may not be limited thereto.

Afterwards, a program operation for changing the polarization of the capacitor CC by the voltage applied to each of the bit line BL and the plate line PL, a read operation for reading data written in the memory cell MC by determining the polarization of the capacitor CC, and the like, may be executed. The program operation and the read operation will be described later.

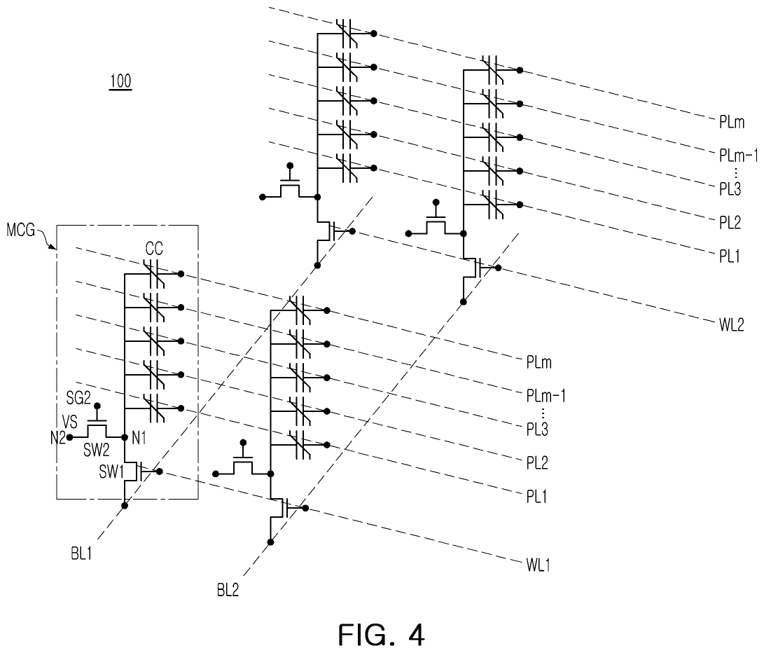

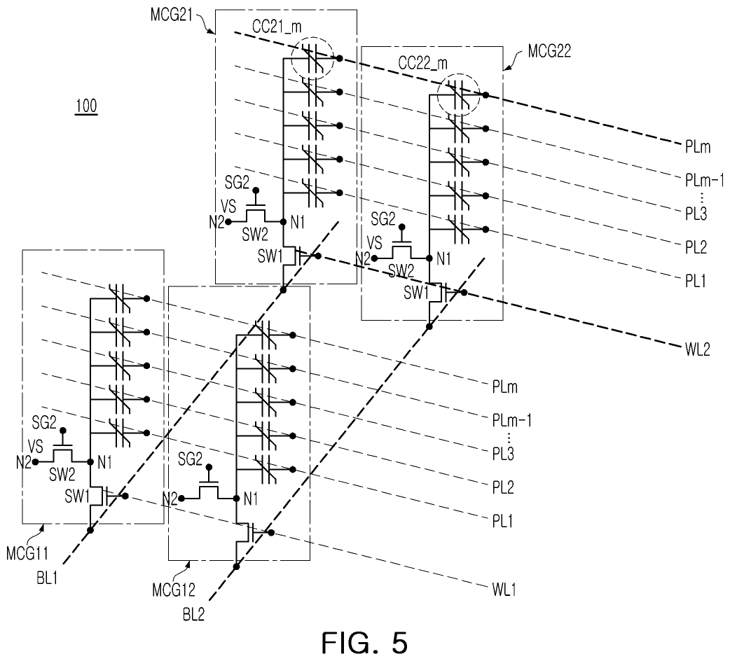

The plurality of memory cells MC of an example embodiment may respectively form memory cell groups. Hereinafter, the memory cell group and operation thereof will be described in detail with reference to FIGS. 4 and 5.

FIG. 4 is a diagram simply illustrating a memory cell array included in a semiconductor device according to an example embodiment. FIG. 5 is a diagram illustrating the operation of the memory cell array of an example embodiment illustrated in FIG. 4.

First, referring to FIG. 4, a memory cell array 100 according to an example embodiment may include a plurality of memory cell groups MCG connected to a plurality of word lines WL1 to WL2, a plurality of plate lines PL1 to PLm, and a plurality of bit lines BL1 to BL2.

In an example embodiment illustrated in FIG. 4, a memory cell group MCG may include a first switching element SW1, a second switching element SW2, and a plurality of capacitors CC. Each of the plurality of capacitors CC may include a ferroelectric layer and may be connected to the first switching element SW1. In detail, the plurality of capacitors CC may share the first switching element SW1. Accordingly, each of the plurality of capacitors CC, the first switching element SW1, and the second switching element SW2 may perform the role of a single memory cell MC described above in FIG. 3.

The second switching element SW2 may be connected between the first node N1 between the first switching element SW1 and the plurality of capacitors CC and the second node N2 that supplies a predetermined voltage VS. The second switching element SW2 may be connected to the second switch control line SG2. For example, each memory cell group MCG may be connected to a different second switch control line SG2. The second node N2 may be connected to a voltage source to which a predetermined voltage VS is set. When the second switching element SW2 is turned on by the second switch control line SG2, a predetermined voltage VS may be applied to the second node N2.

As an example embodiment illustrated in FIG. 4, m capacitors CC may be connected to a first switching element SW1 connected to a first bit line BL1 and a first word line WL1. The m capacitors CC may be connected to different plate lines PL1 to PLm. For example, the m capacitors CC connected to the first switching element SW1 may be matched one-to-one with a plurality of plate lines PL1 to PLm. Accordingly, the polarizations of the plurality of respective capacitors CC sharing one first switching element SW1 may be individually controlled.

Referring to FIG. 5, the operation of the memory cell array 100 of an example embodiment illustrated in FIG. 4 will be described. A selected memory cell may correspond to a memory cell that is a target of a program operation for recording data of a semiconductor device or a read operation for reading recorded data. The selected memory cell may include a selected capacitor.

In an example embodiment illustrated in FIG. 5, the selected capacitors may be the 21st and 22nd capacitors CC21_m and CC22_m, and the selected memory cell groups may be the 21st and 22nd memory cell groups MCG21 and MCG22 including the selected capacitors CC21_m and CC22_m, respectively. The second word line WL2 connected to the selected memory cell groups MCG21 and MCG22 may be a selected word line, and a plurality of bit lines BL1 to BL2 connected to the selected memory cell groups MCG21 and MCG22 may be selected bit lines. Among the plurality of plate lines PL1-PLm, the selected plate line connected to the selected capacitors CC21_m and CC22_m may be a single line, which is the mth plate line PLm.

For example, first switching elements SW1 of selected memory cell groups MCG21 and MCG22 connected to the selected word line WL2 may be turned on by a voltage applied to the selected word line WL2. Second switching elements SW2 of selected memory cell groups MCG21 and MCG22 may be turned off by a voltage applied to the second switch control line SG2. In a state in which the first switching elements SW1 of the selected memory cell groups MCG21 and MCG22 are turned on and the second switching elements SW2 are turned off, only the polarization of the selected capacitors CC21_m and CC22_m connected to the selected plate line (PLm) is changed by the voltage applied to the selected bit line BL1 to BL2 and the selected plate line (PLm), so that the selected capacitors CC21_m and CC22_m may be activated.

To selectively change only the polarization of the selected capacitors CC21_m and CC22_m connected to the selected plate line (PLm), a selection voltage may be applied to the mth plate line PLm connected to the selected memory cell groups MCG21 and MCG22, and the first to m-1-th plate lines PL1 to PLm-1 connected to the selected memory cell groups MCG21 and MCG22 may be floated. At this time, the selection voltage applied to the m plate line PLm may be the same as or different from the voltage applied to the selected bit lines BL1 to BL2.

The 11th and 12th memory cell groups MCG11 and MCG12 excluding the selected memory cell groups MCG21 and MCG22 may be unselected memory cell groups, and the capacitors included in the unselected memory cell groups MCG11 and MCG12 may be unselected capacitors. The first word line WL1 connected to the unselected memory cell groups MCG11 and MCG12 may be an unselected word line, and the first to m plate lines PL1 to PLm connected to the unselected memory cell groups MCG11 and MCG12 may correspond to unselected plate lines.

While the selected capacitors CC21_m and CC22_m are activated, since no voltage is applied to the unselected word line WL1, the first switching elements SW1 of the unselected memory cell groups MCG11 and MCG12 may be turned off. The second switching elements SW2 of the selected memory cell groups MCG21 and MCG22 may be turned on by the voltage applied to the second switch control line SG2. Accordingly, since a predetermined voltage VS is applied to the second node N2, the predetermined voltage VS may be applied to one of the electrodes of the unselected capacitor. In addition, by applying a predetermined voltage VS to the unselected plate lines PL1 to PLm connected to the unselected memory cell groups MCG11 and MCG12, the predetermined voltage VS may also be applied to another one of the electrodes of the unselected capacitor.

For example, the predetermined voltage VS may be lower than the voltage applied to the selected word line WL2. In detail, the predetermined voltage VS may be OV, but the size of the predetermined voltage VS may not be limited thereto.

According to an example embodiment, a predetermined voltage VS may be applied to each of the electrodes of the unselected capacitor, so that a voltage difference may not occur between the electrodes of the unselected capacitor. Accordingly, the coupling effect between the selected plate line (PLm) and the adjacent unselected plate lines PL1 to PLm may be reduced, thereby preventing data stored in the unselected capacitor from being damaged or changed and preventing leakage current from occurring in the unselected capacitor.

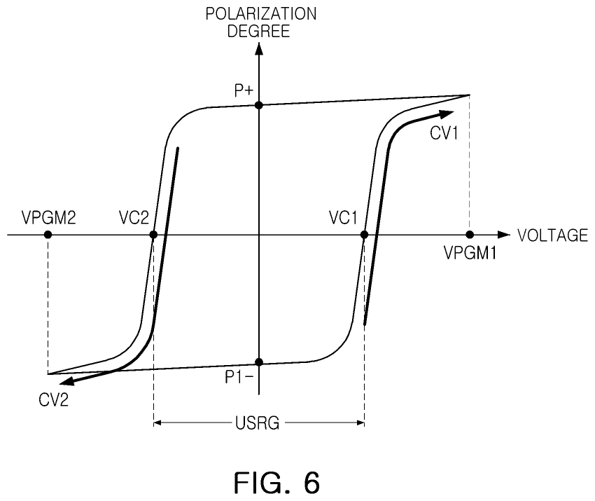

The polarization of the ferroelectric layer changes depending on the voltage applied to the capacitor, and for example, the relationship between the voltage and the polarization may be expressed as a hysteresis curve. This will be described in more detail below with reference to FIG. 6.

FIG. 6 is a drawing illustrating the characteristics of a memory cell included in a semiconductor device according to an example embodiment.

FIG. 6 may be a graph illustrating the relationship between a voltage applied to a memory cell and the polarization of a ferroelectric layer included in the memory cell. As illustrated in FIG. 6, the relationship between the voltage applied to the memory cell and the polarization of a ferroelectric layer included in the memory cell may be expressed as a hysteresis curve.

Referring to the graph illustrated in FIG. 6, under the condition that a positive voltage is applied to the memory cell, the polarization of the ferroelectric layer may increase in a specific direction along the first curve CV1. At this time, the positive voltage at which the polarization of the ferroelectric layer is saturated may be the first program voltage VPGM1. For example, a positive voltage may be applied to the memory cell by setting the voltage of the plate line connected to the memory cell higher than the voltage of the bit line connected to the memory cell. The polarization of the ferroelectric layer may be changed by the positive voltage applied to the memory cell. Afterwards, even if the voltage applied to the memory cell is blocked, the polarization of the ferroelectric layer may be maintained as a positive polarization (P+).

On the other hand, when a negative voltage is applied to the memory cell, the polarization of the ferroelectric layer may be changed from the positive polarization (P+) to a different direction along the second curve CV2. At this time, the negative voltage at which the polarization of the ferroelectric layer is saturated may be the second program voltage VPGM2. By setting the voltage of the plate line connected to the memory cell to be lower than the voltage of the bit line connected to the memory cell, a negative voltage may be applied to the memory cell. The polarization of the ferroelectric layer included in the memory cell is reduced to the negative polarization (P−) by the negative voltage, and even if the voltage applied to the memory cell is blocked, the negative polarization (P−) may be maintained as it is.

In this manner, by changing the polarization of the ferroelectric layer to one of the negative and positive directions, data may be written to the memory cell. For example, a state in which the polarization of the ferroelectric layer is changed in the negative direction may be defined as a state in which the first data is written to the memory cell, and a state in which the polarization of the ferroelectric layer is changed in the positive direction may be defined as a state in which the second data is written to the memory cell. Assuming that 1 bit of data is written to the memory cell, one of the first data and the second data may correspond to ‘0,’ and the other may correspond to ‘1.’

In an example embodiment, a read operation on the memory cell may be executed by applying a read voltage, which is a positive voltage, to the memory cell while the first switching element included in the memory cell is turned on. For example, in the case of a memory cell in which the first data is written, since the ferroelectric layer has a positive polarization (P+), the polarization of the ferroelectric layer may hardly be changed by the read voltage, which is a positive voltage. Therefore, the voltage of the capacitor including the ferroelectric layer may be detected as relatively small.

On the other hand, in the case of the memory cell in which the second data is recorded, since the ferroelectric layer has a negative polarization (P−), the polarization of the ferroelectric layer changes relatively significantly by the read voltage, which is a positive voltage, and the voltage of the capacitor may be detected relatively significantly in the read operation.

In the read operation, the voltage of the capacitor is detected from the bit line connected to the memory cell, and may be determined based on the difference between the polarization of the ferroelectric layer of the memory cell before the read operation and the polarization of the ferroelectric layer by the read voltage applied to the memory cell.

To perform the above program operation and read operation for the selected memory cell, a voltage may be applied to the selected plate line so that the selected memory cell memory cell may be activated. The voltage applied to the selected plate line may cause a coupling effect between the selected plate line and the unselected plate line adjacent to the selected plate line. The coupling effect may induce an abnormal voltage in the unselected memory cell, which may affect the data of the unselected memory cell.

For example, a positive voltage may be applied to an unselected memory cell that maintains a negative polarization (P−) by a coupling effect. The polarization of the ferroelectric layer included in the unselected memory cell may increase to a positive polarization (P+), thereby changing recorded data. As another example, a negative voltage may be applied to an unselected memory cell that maintains a positive polarization (P+) by a coupling effect. The polarization of the ferroelectric layer included in the unselected memory cell may decrease, thereby causing charge leakage.

In an example embodiment, while the selected memory cell is activated, the voltage applied to the unselected memory cell may be maintained within the unselected range (USRG). The maximum value of the unselected range (USRG) of the example embodiment illustrated in FIG. 6 is the first threshold voltage VC1, and the first threshold voltage VC1 may be a positive voltage. The minimum value of the unselected range (USRG) is the second threshold voltage VC2, and the second threshold voltage VC2 may be a negative voltage.

For example, the magnitudes of the first program voltage VPGM1 and the second program voltage VPGM2 may be the same, and only the polarities may be opposite to each other. The first threshold voltage VC1 may correspond to half of the first program voltage VPGM1, and the second threshold voltage VC2 may correspond to half of the second program voltage VPGM2. In detail, the magnitudes of the first threshold voltage VC1 and the second threshold voltage VC2 may be the same, and only the polarities may be opposite to each other.

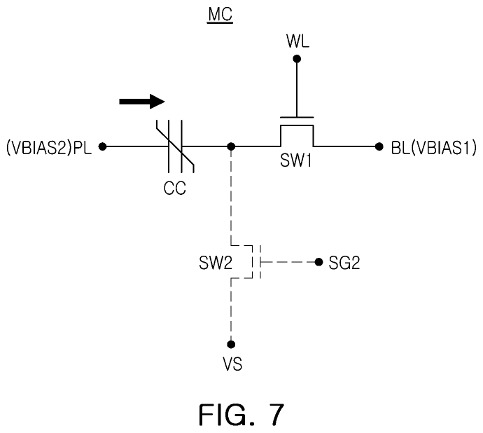

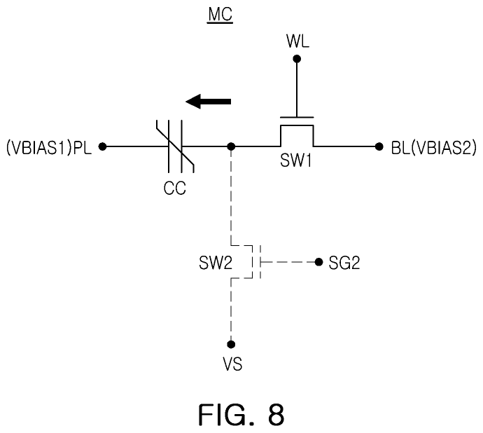

FIG. 7 and FIG. 8 are drawings illustrating program operations of a semiconductor device according to an example embodiment.

First, referring to FIG. 7, FIG. 7 may be a drawing illustrating a program operation for writing first data to a memory cell MC. In a program operation for recording the first data, the first switching element SW1 may be turned on by a voltage applied to the word line WL, and the second switching element SW2 may be turned off by a voltage applied to the second switch control line SG2. In a state in which the first switching element SW1 is turned on, a first bias voltage VBIAS1 may be applied to the bit line BL, and a second bias voltage VBIAS2 may be applied to the plate line PL. The second bias voltage VBIAS2 is greater than the first bias voltage VBIAS1, and the first bias voltage VBIAS1 may be a reference voltage such as a ground voltage.

The difference between the first bias voltage VBIAS1 and the second bias voltage VBIAS2 is defined as the first program voltage VPGM1, and the first program voltage VPGM1 may be a positive voltage. Referring to FIG. 6, which shows a hysteresis curve of a memory cell MC, the polarization of the ferroelectric layer included in the capacitor CC may be changed to a positive polarization (P+) by the first program voltage VPGM1. Even after the voltage supply to each of the plate line PL and the bit line BL is cut off, the polarization of the ferroelectric layer is maintained as a positive polarization (P+), and the first data written to the memory cell MC may be maintained.

Referring to FIG. 8, FIG. 8 may be a drawing illustrating a program operation for writing second data to the memory cell MC. In the program operation for writing the second data, the first switching element SW1 may be turned on by the voltage applied to the word line WL, and the second switching element SW2 may be turned off by the voltage applied to the second switch control line SG2. A first bias voltage VBIAS1 may be applied to the plate line PL, and a second bias voltage VBIAS2 may be applied to the bit line BL. As with the example described with reference to FIG. 7, the second bias voltage VBIAS2 is greater than the first bias voltage VBIAS1, and the first bias voltage VBIAS1 may be a reference voltage such as a ground voltage.

The difference between the first bias voltage VBIAS1 and the second bias voltage VBIAS2 is defined as the second program voltage VPGM2, and the second program voltage VPGM2 may be a negative voltage. For example, the magnitudes of the first program voltage VPGM1 and the second program voltage VPGM2 may be the same, but their polarities may be opposite to each other.

Referring to FIG. 6, which illustrates a hysteresis curve of a memory cell MC, the polarization of a ferroelectric layer included in a capacitor CC may be changed from a positive polarization (P+) to a negative polarization (P−) by a second program voltage VPGM2. Even after the voltage supply to each of the plate line PL and the bit line BL is cut off, the polarization of the ferroelectric layer is maintained as a negative polarization (P−), and the second data written to the memory cell MC may be maintained.

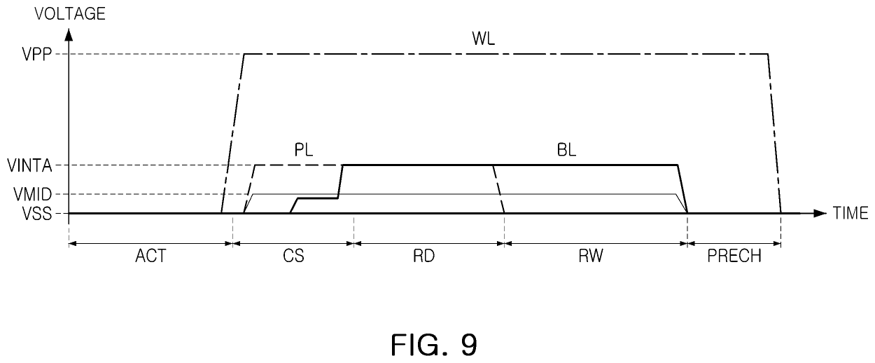

FIG. 9 is a drawing illustrating a read operation of a semiconductor device according to an example embodiment.

Specific embodiments of the semiconductor device may be similar to those described above in FIGS. 1 to 8. Referring to FIG. 9, the read operation may include an activation period ACT, a charge sharing period CS, a sensing period RD, a write period RW, and a precharge period PRECH.

First, in the activation period ACT, a turn-on voltage VPP may be input to a selected word line WL connected to a selected memory cell group, so that a first switching element included in the selected memory cell group may be turned on. The second switching element may be turned off by a voltage applied to a second switch control line connected to the selected memory cell group. Accordingly, the selected memory cell group may be activated. For example, while a turn-on voltage VPP is applied to a selected word line WL, a voltage applied to a second switch control line may have a voltage corresponding to a logic low, thereby turning off the second switching element.

Thereafter, in a charge sharing period CS, a second voltage VINTA may be input to a selected plate line PL connected to a selected memory cell. A selected bit line BL connected to a selected memory cell group may be floated during a portion of the sharing period CS. At this time, the selected memory cell may correspond to a selected capacitor among the first switching element, the second switching element, and the capacitors, and the selected plate line PL may be a line connected to the selected capacitor.

In an example embodiment, the first voltage VSS may be a ground voltage, and the second voltage VINTA may be greater than the first voltage VSS and less than the turn-on voltage VPP. A positive voltage is applied to the selected memory cell by the first voltage VSS and the second voltage VINTA, and the polarization of the selected capacitor may be set to a positive polarization.

In the sensing period RD, the voltage of the selected capacitor to which the first voltage VSS and the second voltage VINTA are applied may be detected by the sense amplifier from the selected bit line BL. For example, assuming that the first data DO was written to the selected memory cell before the read operation was started, the polarization of the selected capacitor hardly changes in the charge sharing period CS, and thus, the voltage of the selected bit line BL may hardly change from the first voltage VSS.

On the other hand, assuming that the second data D1 was written to the selected memory cell before the read operation was started, the polarization of the selected capacitor changes from a negative polarization to a positive polarization in the charge sharing period CS, so the voltage of the selected bit line BL may relatively greatly increase. The sense amplifier may amplify the voltage of the selected bit line BL in the sensing period RD and compare the amplified voltage with the reference voltage.

In an example embodiment illustrated in FIG. 9, the reference voltage compared with the voltage of the selected bit line BL may be the intermediate voltage VMID. If the voltage of the selected bit line BL is lower than the reference voltage, the data of the selected memory cell may be read as the first data DO, and if the voltage of the selected bit line BL is higher than the reference voltage, the data of the selected memory cell may be read as the second data D1.

When the data of the selected memory cell is read, the voltage of the selected plate line PL may be reduced to the first voltage VSS. Thereafter, a write operation that restores the data of the selected memory cell changed in the charge sharing period CS may be executed during the write period RW. The data of the selected memory cell may be changed to the first data DO by the positive voltage input to the selected memory cell in the charge sharing period CS.

Accordingly, as illustrated in FIG. 9, if the data of the selected memory cell is read as the first data DO, a separate write operation may not be executed. On the other hand, if the data of the selected memory cell is read as the second data D1, by maintaining the voltage of the selected bit line BL at the second voltage VINTA during the write period RW, the second data D1 may be written again to the selected memory cell in which the first data DO was written in the charge sharing period CS. When the write period RW is terminated, an operation of reducing the voltage of the selected bit line BL to the first voltage VSS may be executed during the precharge period PRECH.

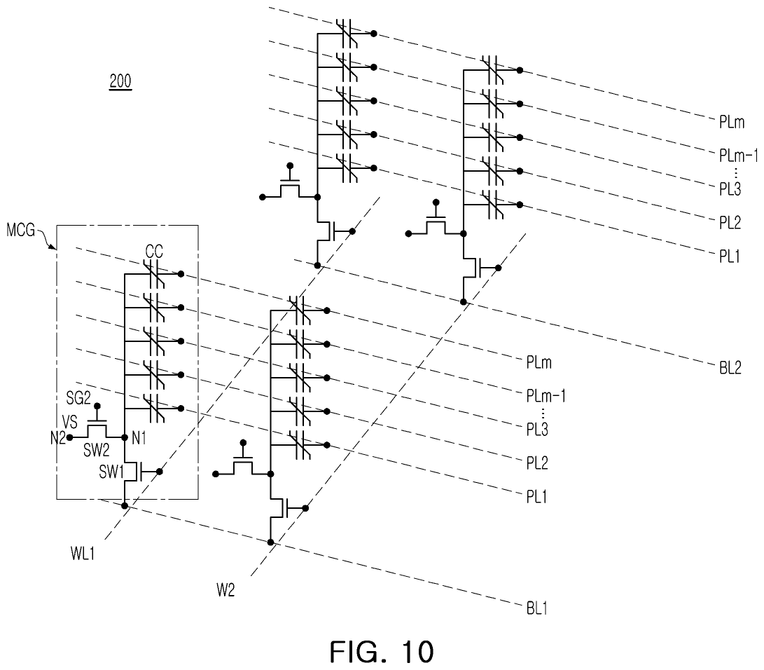

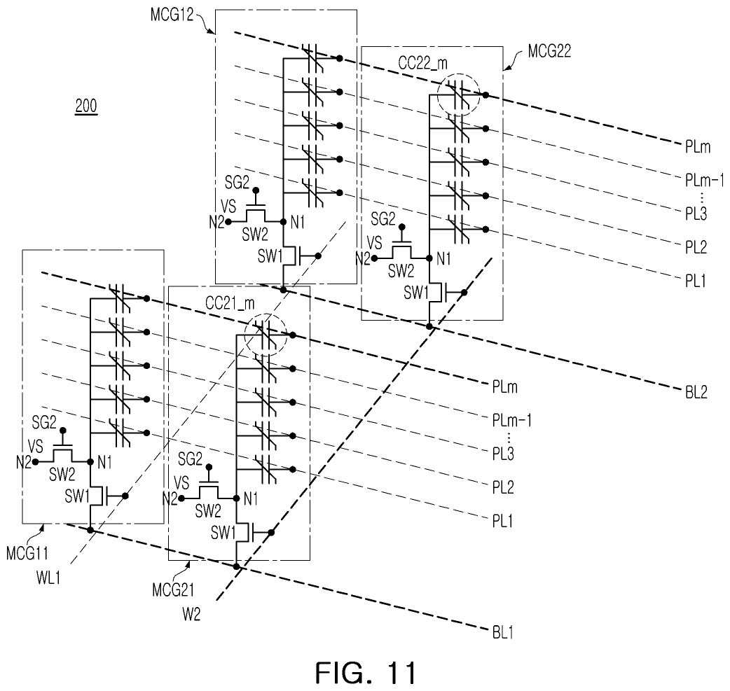

FIG. 10 is a diagram simply illustrating a memory cell array included in a semiconductor device according to an example embodiment. FIG. 11 is a diagram illustrating the operation of the memory cell array of an example embodiment illustrated in FIG. 10.

First, referring to FIG. 10, a memory cell array 200 according to an example embodiment may include a plurality of memory cell groups connected to a plurality of word lines WL1 to WL2, a plurality of plate lines PL1 to PLm, and a plurality of bit lines BL1 to BL2.

The memory cell group MCG may include a first switching element SW1, a second switching element SW2, and a plurality of capacitors CC including a ferroelectric layer. The second switching element SW2 may be connected between a first node N1 between the first switching element SW1 and the plurality of capacitors CC and a second node N2 supplying a predetermined voltage VS. The second switching element SW2 may be connected to the second switch control line SG2 to which a predetermined voltage VS is applied.

Specific embodiments of the memory cell array 200 may be similar to those described above in FIGS. 4 and 5.

Comparing FIGS. 4 and 10, the arrangement structures among the plurality of plate lines PL1 to PLm, the plurality of word lines WL1 to WL2, and the plurality of bit lines BL1 to BL2 may be different. In the memory cell array 100 of the example embodiment illustrated in FIG. 4, the plurality of plate lines PL1 to PLm may be parallel to the plurality of word lines WL1 to WL2 and perpendicular to the plurality of bit lines BL1 to BL2. On the other hand, in the memory cell array 200 of an example embodiment illustrated in FIG. 10, the plurality of plate lines PL1 to PLm may be parallel to the plurality of bit lines BL1 to BL2 and perpendicular to the plurality of word lines WL1 to WL2.

Referring to FIG. 11, the operation of the memory cell array 200 of an example embodiment illustrated in FIG. 10 will be described. In an example embodiment illustrated in FIG. 11, the selected capacitor may be the 21st and 22nd capacitors CC21_m and CC22_m, and the selected memory cell group may be the 21st and 22nd memory cell groups MCG21 and MCG22 including the selected capacitors CC21_m and CC22_m. The second word line WL2 connected to the selected memory cell groups MCG21 and MCG22 is a selected word line, and the plurality of bit lines BL1 to BL2 connected to the selected memory cell groups MCG21 and MCG22 may be selected bit lines.

Comparing FIG. 5 and FIG. 11, there may be a difference in the number of selected plate lines connected to the selected capacitors CC21_m and CC22_m. In an example embodiment illustrated in FIG. 5, the selected capacitors CC21_m and CC22_m may be connected to the same m-th plate line PLm. In detail, the selected plate line may be a single line. On the other hand, in an example embodiment illustrated in FIG. 11, the selected capacitors CC21_m and CC22_m may be connected to different m-th plate lines PLm. In detail, the selected plate line may be a plurality of plate lines.

The 11th and 12th memory cell groups MCG11 and MCG12 excluding the selected memory cell groups MCG21 and MCG22 may be unselected memory cell groups, and the capacitors included in the unselected memory cell groups MCG11 and MCG12 may be unselected capacitors. The first word line WL1 connected to the unselected memory cell groups MCG11 and MCG12 may be an unselected word line.

Comparing FIG. 5 and FIG. 11, whether the unselected memory cell group is connected to the selected plate line may be different. Referring to FIG. 5, the unselected memory cell groups MCG21 and MCG22 may not be connected to the selected plate line PLm. On the other hand, referring to FIG. 11, the unselected memory cell groups MCG21 and MCG22 may be connected to different selected plate lines PLm.

Referring to FIG. 5 and FIG. 11, while the selected capacitors CC21_m and CC22_m are activated, the second switching elements SW2 of the unselected memory cell groups MCG11 and MCG12 may be turned on, so that a predetermined voltage VS may be applied to one of the electrodes of the unselected capacitor. Accordingly, a voltage difference may not occur between the electrodes of the unselected capacitor. For example, the second switching elements SW2 included in the unselected memory cell groups MCG21 and MCG22 may maintain a turn-on state during the charge sharing period CS to the pre-charge period PRECH of FIG. 9.

However, since the unselected memory cell groups MCG21 and MCG22 of FIG. 11 are connected to different selected plate lines PLm, the magnitude of the predetermined voltage VS may be different from that in the example embodiment of FIG. 5.

First, the predetermined voltage VS of an example embodiment of FIG. 5 may be the first voltage VSS of FIG. 9. In detail, the predetermined voltage VS may be a ground voltage (0 V). The second switching elements SW2 included in the unselected memory cell groups MCG21 and MCG22 of FIG. 5 may maintain a turn-on state while the selected capacitor is activated.

On the other hand, the predetermined voltage VS of an example embodiment of FIG. 11 may be a positive voltage, and in detail, may be equal to or less than the second voltage VINTA applied to the selected word line WL2. For example, the magnitude of the predetermined voltage VS may be half of the second voltage VINTA. However, the magnitude of the predetermined voltage VS may not be limited thereto.

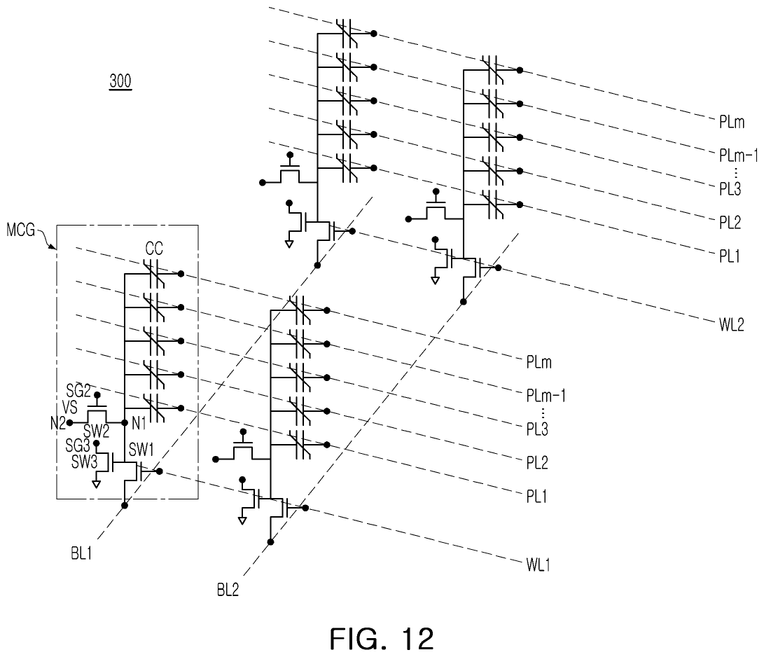

FIG. 12 is a drawing simply illustrating a memory cell array included in a semiconductor device according to an example embodiment.

First, referring to FIG. 12, a memory cell array 300 according to an example embodiment may include a plurality of memory cell groups connected to a plurality of word lines WL1 to WL2, a plurality of plate lines PL1 to PLm, and a plurality of bit lines BL1 to BL2.

A memory cell group MCG may include a first switching element SW1, a second switching element SW2, and a plurality of capacitors CC including a ferroelectric layer. The second switching element SW2 may be connected between a first node N1 between the first switching element SW1 and the plurality of capacitors CC and a second node N2 that supplies a predetermined voltage VS. The second switching element SW2 may be connected to a second switch control line SG2 to which a predetermined voltage VS is applied.

Comparing FIG. 10 with FIG. 12, the memory cell array 300 of an example embodiment illustrated in FIG. 12 may further include a third switching element SW3. The third switching element SW3 may be implemented as a transistor. The third switching element SW3 may be connected between the first switching element SW1 and a plurality of capacitors. In detail, the gate of the third switching element SW3 may be connected to one of the electrodes of the capacitors CC. One of the source/drain regions of the third switching element SW3 may be connected to a ground voltage, and the other of the source/drain regions of the third switching element SW3 may be connected to a third switch control line SG3. For example, each memory cell group MCG may be connected to a different third switch control line SG3.

In an example embodiment illustrated in FIG. 12, the third switch control line SG3 may correspond to a read bit line, and the bit line BL may correspond to a program bit line. The third switch control line SG3 is connected to the sense amplifier circuit 33 described above in FIG. 1, and the sense amplifier circuit 33 of FIG. 1 may perform a read operation on a selected memory cell through the third switch control line SG3.

While the program operation on the selected memory cell is performed, the third switching element SW3 may be turned off by the voltage applied to the third switch control line SG3. At this time, the voltage applied to the third switch control line SG3 may be a low level or a high level. While a read operation is performed on the selected memory cell, a high level voltage is applied to the third switch control line SG3, and the bit line BL may be maintained in a floating state. At this time, the sense amplifier circuit may detect a change in the voltage applied to the third switch control line SG3 and read data written in the selected memory cell.

The operations of the first switching element SW2 and the second switching element SW2 of the example embodiment illustrated in FIG. 12 may be similar to those described above in FIG. 11.

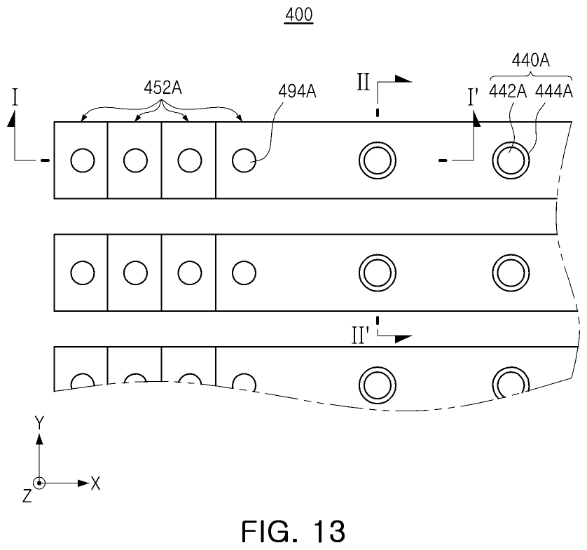

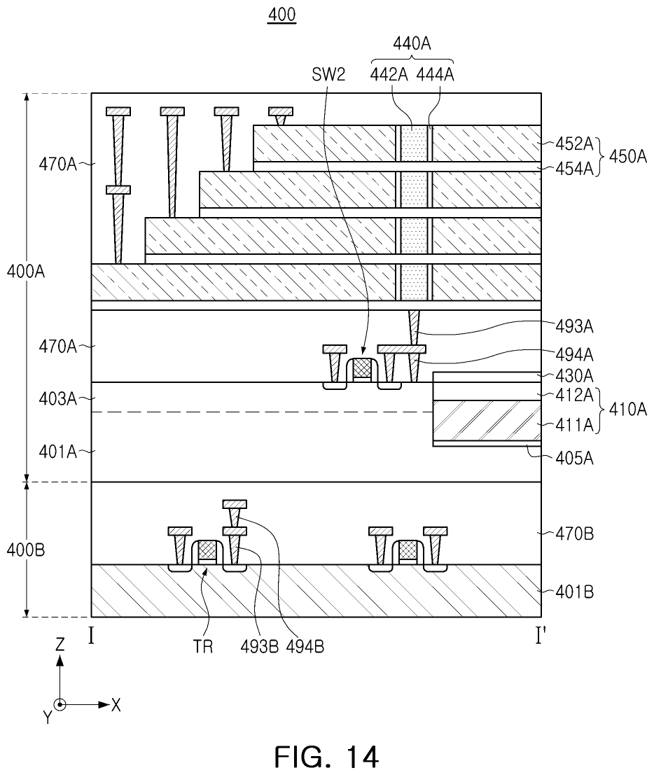

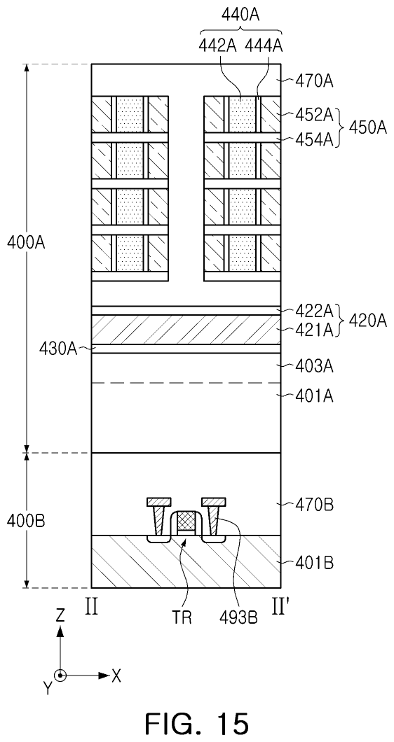

FIG. 13 is a plan view illustrating a semiconductor device according to an example embodiment. FIG. 14 is a cross-sectional view illustrating a cross-section of the semiconductor device illustrated in FIG. 13 in the direction of I-I′. FIG. 15 is a cross-sectional view illustrating a cross-section of the semiconductor device illustrated in FIG. 13 in the direction of II-II′.

In the example embodiments illustrated in FIGS. 13 to 15, a semiconductor device 400 according to an example embodiment may include an A region 400A and a B region 400B.

Referring to FIGS. 13 to 15, the A region 400A may correspond to a memory cell layer in which a plurality of memory cells are formed, and the memory cell layer may correspond to the memory cell array 100 described above in FIGS. 5 and 6. The B region 400B may correspond to a core peripheral layer in which a plurality of sub-word line drivers, a plurality of sense amplifiers, and the like are formed, excluding a plurality of memory cells. For example, the B region 400B may correspond to the peripheral circuit region 30 described above in FIG. 1, and may include a word line driving circuit 31, a plate line driving circuit 32, a sense amplifier circuit 33, a data input/output circuit 34, a control logic 35, and the like, and may control the memory cell layer of the A region 400A.

In the A region 400A, an active region 403A, a gate structure 410A providing a word line, a bit line structure 420A connected to the active region 403A, a capacitor structure 440A, a plate line structure 450A, a second switching element SW2 and the like may be formed. The gate structure 410A may intersect the active region 403A and the bit line structure 420A, and may be buried in the substrate 401A.

The gate structure 410A may include a gate electrode layer 411A, a capping layer 412A, and the like. The gate electrode layer 411A may be formed of a conductive material such as a metal or a metal compound. The capping layer 412A may be formed of an insulating material such as silicon nitride. A gate insulating layer 405A may be disposed between the gate electrode layer 411A and the substrate 401A, and the gate insulating layer 405A may be formed of silicon oxide, or the like.

The active region 403A may be doped with impurities and may provide a source region and a drain region of a switching element included in a memory cell. The active region 403A may be connected to a capacitor structure 440A through a plurality of interconnection patterns 493A and 494A.

The second switching element SW2 may be formed adjacent to the gate structure 410A. One of the source/drain regions of the second switching element SW2 may be connected to a second switch control line (not illustrated) through a plurality of interconnection patterns 493A and 494A. Another one of the source/drain regions of the second switching element SW2 may be connected to the capacitor structure 440A and the active region 403A through a plurality of interconnection patterns 493A and 494A.

The bit line structure 420A may be buried in the intermediate insulating layer 430A and the insulating layer 470A. The bit line structure 420A may include a bit line conductive layer 421A, a bit line capping layer 422A, and a spacer layer (not illustrated).

The plate line structure 450A may include a plate line conductive layer 452A, a plate line capping layer 454A, and the like. The plate line conductive layer 452A may be formed of a conductive material such as a metal or a metal compound. The plate line capping layer 454A may be formed of an insulating material such as silicon nitride.

The A region 400A may include a plurality of plate line structures 450A. The plurality of plate line structures 450A may be stacked in a third direction (Z-axis direction). As an example embodiment illustrated in FIGS. 14 and 15, the A region 400A may include four plate line structures 450A stacked in the third direction. Referring to FIG. 13, the four plate line structures 450A stacked in the third direction may be arranged in the second direction (Y-axis direction). For example, the four plate line structures 450A stacked in the third direction may be connected to the same memory cell group, and the plate line structures 450A arranged in the second direction may be respectively connected to a different memory cell group.

The capacitor structure 440A may be connected to the active region 403A through a plurality of interconnection patterns 493A and 494A. The capacitor structure 440A may include a ferroelectric layer 442A, a dielectric layer 444A, and the like. The capacitor structure 440A may extend in a third direction perpendicular to the upper surfaces of the substrates 401A and 401B.

The ferroelectric layer 442A may include a ferroelectric material, and may include at least one of hafnium (Hf), zirconium (Zr), silicon (Si), yttrium (Y), aluminum (Al), gadolinium (Gd), strontium (Sr), lanthanum (La), titanium (Ti), scandium (Sc), and oxides thereof. The dielectric layer 444A may include an insulating material, and may include silicon oxide (SiO), silicon nitride (SiN), silicon oxynitride (SiON), a high-k material, or combinations thereof.

In the B region 400B, a substrate 401B, a plurality of semiconductor elements TR formed on the substrate 401B, a B insulating layer 470B, a plurality of interconnection patterns 493B and 494B formed in the B insulating layer 470B and connected to the plurality of semiconductor elements TR, and the like may be formed. The plurality of interconnection patterns 493B and 494B may include a device contact 493B and a lower wiring 494B. The semiconductor element TR may configure a word line driving circuit, a sense amplifier circuit, a plate line driving circuit, or the like.

Referring to FIGS. 13 to 15, the A region 400A and the B region 400B may be stacked in a third direction. The A region 400A may be stacked on the B region 400B. Accordingly, the plan view of the semiconductor device 400 of the example embodiment illustrated in FIG. 13 may correspond to the plane of the A region 400A. The semiconductor device 400 may have a chip-on-package (CoP) structure, but may not be limited thereto.

In the A region 400A, the plate line structure 450A may be formed on the gate structure 410A, the bit line structure 420A, and the second switching element SW2 in the third direction. At this time, the capacitor structure 440A may be formed to penetrate the plate line structures 450A in the third direction.

In an example embodiment illustrated in FIGS. 13 to 15, the plate line structure 450A and the gate structure 410A may extend in the first direction (X-axis direction). In detail, the plate line structure 450A and the gate structure 410A may overlap in the third direction. The bit line structure 420A may extend in the second direction.

In another example different from the example embodiment illustrated in FIGS. 13 to 15, the plate line structure and the bit line structure may extend in the first direction, and the gate structure may extend in the second direction. In detail, the plate line structure and the bit line structure may overlap in the third direction. This may correspond to the memory cell array 200 described above in FIGS. 10 and 11.

As set forth above, according to an example embodiment, by applying the same voltage to respective electrodes of unselected capacitors connected to an unselected word line, the polarization of the unselected capacitors may be maintained within a predetermined range, thereby improving reliability and performance of a semiconductor device recording data, and the like.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a cell region provided with memory cell groups connected to word lines, bit lines, and plate lines, each of the memory cell groups including a first switching element, a second switching element, and capacitors connected to the first switching element and including a ferroelectric layer, the second switching element being connected between a first node between the first switching element and the capacitors and a second node supplying a predetermined voltage; and
a peripheral circuit region controlling the cell region through the word lines, the bit lines, and the plate lines,
wherein in each of the memory cell groups, the capacitors are connected to the plate lines different from each other,
wherein the peripheral circuit region applies a turn-on voltage to a selected word line connected to a selected memory cell group among the memory cell groups, from among the word lines, and turns on the first switching element included in the selected memory cell group, and
wherein while the selected memory cell group is activated, the peripheral circuit region applies the predetermined voltage to unselected plate lines connected to unselected memory cell groups excluding the selected memory cell group among the memory cell groups, and turns on the second switching element included in each of the unselected memory cell groups.

2. The semiconductor device of claim 1, wherein among the plate lines, a selected plate line connected to a selected capacitor among the capacitors included in the selected memory cell group is a single line.

3. The semiconductor device of claim 2, wherein in each of the memory cell groups, the first switching element is connected to one of the word lines and one of the bit lines.

4. The semiconductor device of claim 3, wherein in the peripheral circuit region, while the selected memory cell group is activated, a first voltage is applied to the selected plate line, a second voltage greater than the first voltage is applied to a selected bit line connected to the selected memory cell group from among the bit lines, the second voltage is applied to the selected plate line and the selected bit line, the second voltage is applied to the selected plate line, and the first voltage is applied to the selected bit line.

5. The semiconductor device of claim 1, wherein in each of the memory cell groups, the second node is connected to a voltage source set to the predetermined voltage.

6. The semiconductor device of claim 5, wherein the predetermined voltage is a first voltage, and the first voltage is lower than the turn-on voltage.

7. The semiconductor device of claim 6, wherein the first voltage is 0 V.

8. The semiconductor device of claim 1, wherein each of the first switching element and the second switching element is implemented as a transistor.

9. The semiconductor device of claim 1, wherein the peripheral circuit region includes a word line driving circuit including word line drivers connected to the word lines, a sense amplifier circuit including sense amplifiers connected to the bit lines, and a plate line driving circuit including plate line drivers connected to the plate lines.

10. A semiconductor device comprising:
a first region including a plurality of memory cell groups, each of the plurality of memory cell groups including a first switching element, a second switching element, and a plurality of capacitors including a ferroelectric layer; and
a second region including a plurality of word line driving circuits, a plurality of sense amplifier circuits, and a plurality of plate line drivers,
wherein the first region includes a plurality of word lines extending in a first direction, a plurality of bit lines extending in a second direction perpendicular to the first direction, and a plurality of plate lines,
wherein the first switching element is connected to one of the plurality of word lines and one of the plurality of bit lines,
wherein the plurality of plate lines are disposed on the plurality of word lines, the plurality of bit lines, and the second switching element in a third direction, perpendicular to the first direction and the second direction, and are stacked in the third direction,
wherein in each of the memory cell groups, the plurality of capacitors penetrate the plurality of plate lines in the third direction, and the capacitors are connected to the plurality of plate lines different from each other, and
wherein the second switching element is connected to a voltage source located between the first switching element and the plurality of capacitors and set to a predetermined voltage.

11. The semiconductor device of claim 10, wherein the plate lines extend in the first direction.

12. The semiconductor device of claim 11, wherein the plate lines overlap with the word lines in the third direction.

13. The semiconductor device of claim 11, wherein the predetermined voltage is 0 V.

14. The semiconductor device of claim 10, wherein the plate lines extend in the second direction.

15. The semiconductor device of claim 14, wherein the plate lines overlap with the bit lines in the third direction.

16. The semiconductor device of claim 14, wherein the predetermined voltage is a positive voltage.

17. A semiconductor device comprising:
a plurality of word lines;
a plurality of bit lines;
a plurality of plate lines; and
a plurality of memory cell groups connected to the plurality of word lines, the plurality of plate lines, and the plurality of bit lines,
wherein each of the plurality of memory cell groups includes a first switching element, a second switching element, and a plurality of capacitors connected to the first switching element and including a ferroelectric layer, and
wherein in each of the plurality of memory cell groups, the first switching element is connected to one of the word lines and one of the bit lines, the plurality of capacitors are connected to the plurality of plate lines different from each other, and the second switching element is connected between the first switching element and the plurality of capacitors.

18. The semiconductor device of claim 17, wherein in each of the memory cell groups, the second switching element is connected to a voltage source set to a predetermined voltage.

19. The semiconductor device of claim 17, wherein each of the memory cell groups further includes a third switching element connected between the first switching element and the plurality of capacitors.

20. The semiconductor device of claim 19, wherein in each of the memory cell groups, the third switching element is connected to a ground voltage.
